(19) United States
(12) Patent Application Publication
(10) Pub. No.: US 2013/0075751 A1
(43) Pub. Date: Mar. 28, 2013

(54) COMPOUND SEMICONDUCTOR DEVICE AND METHOD OF MANUFACTURING THE SAME

(71) Applicant: Kenji IMANISHI, Atsugi (JP)

(72) Inventor: Kenji IMANISHI, Atsugi (JP)

(73) Assignee: Fujitsu Limited, Kawasaki-shi (JP)

(21) Appl. No.: 13/586,078

(22) Filed: Aug. 15, 2012

(30) Foreign Application Priority Data
Sep. 28, 2011 (JP) 2011-212994

(51) Int. Cl. H01L 29/778; H01L 21/335; H01L 29/205

(52) U.S. Cl. 257/76; 257/194; 438/172; 257/E29.091; 257/E29.246; 257/E21.403

(57) ABSTRACT

An embodiment of a compound semiconductor device includes: a substrate; an electron channel layer and an electron supply layer formed over the substrate; a gate electrode, a source electrode and a drain electrode formed on or above the electron supply layer; a p-type semiconductor layer formed between the electron supply layer and the gate electrode; and a hole barrier layer formed between the electron supply layer and the p-type semiconductor layer, a band gap of the hole barrier layer being larger than that of the electron supply layer.

### CROSS-REFERENCE TO RELATED APPLICATION

This application is based upon and claims the benefit of priority of the prior Japanese Patent Application No. 2011-212994, filed on Sep. 28, 2011, the entire contents of which are incorporated herein by reference.

### FIELD

The embodiments discussed herein are related to a compound semiconductor device and a method of manufacturing the same.

### BACKGROUND

In recent years, there has been vigorous development of electronic devices (compound semiconductor devices) having a GaN layer and an AlGaN layer sequentially formed over a substrate, wherein the GaN layer is used as an electron channel layer. One of the compound semiconductor device is known as a GaN-based high electron mobility transistor (HEMT). The GaN-based HEMT makes a wise use of a high density two-dimensional gas (2DEG) which generates at the heterojunction interface between AlGaN and GaN.

The band gap of GaN is 3.4 eV, which is larger than the band gap of Si (1.1 eV) and the band gap of GaAs (1.4 eV). In other words, GaN has a large breakdown field strength. GaN also has a large saturation electron velocity. GaN is, therefore, a material of great promise for compound semiconductor devices operable under high voltage and capable of yielding large output. The GaN-based HEMT is therefore expected as high-efficiency switching devices, and high-breakdown-voltage power devices for electric vehicles, and so forth.

Most of the GaN-based HEMTs, which utilize high density two-dimensional gas, perform normally-on operation. In short, a current may flow, even when the gate voltage is off. The reason is that a lot of electrons exist in the channel. On the other hand, normally-off operation is important for a GaN-based HEMT for high-breakdown-voltage power devices in view of a fail-safe.

Investigations into various techniques have therefore been directed to achieve a GaN-based HEMT capable of normally-off operation. For example, there is a structure in which a p-type GaN layer containing p-type impurity such as Mg is formed between the gate electrode and the activated region.

However, it is very difficult to obtain good conduction characteristics such as on-resistance and operation speed.
[Patent Literature 1] Japanese Laid-Open Patent Publication No. 2010-258313

### SUMMARY

According to an aspect of the embodiments, a compound semiconductor device includes: a substrate; an electron channel layer and an electron supply layer formed over the substrate; a gate electrode, a source electrode and a drain electrode formed on or above the electron supply layer; a p-type semiconductor layer formed between the electron supply layer and the gate electrode; and a hole barrier layer formed between the electron supply layer and the p-type semiconductor layer, a band gap of the hole barrier layer being larger than that of the electron supply layer.

According to another aspect of the embodiments, a method of manufacturing a compound semiconductor device includes: forming an electron channel layer and an electron supply layer over the substrate; forming a gate electrode, a source electrode and a drain electrode on or above the electron supply layer; forming a p-type semiconductor layer which is located between the electron supply layer and the gate electrode, before the forming the gate electrode; and forming a hole barrier layer which is located between the electron supply layer and the p-type semiconductor layer, before the forming the p-type semiconductor layer, a band gap of the hole barrier layer being larger than that of the electron supply layer.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a cross sectional view illustrating a structure of a compound semiconductor device according to a first embodiment;

FIG. 2 is a diagram illustrating a band structure beneath a gate electrode of a GaN-based HEMT;

FIG. 3A is a cross sectional view illustrating a structure of a referential example;

FIG. 3B is a diagram illustrating a band structure of the referential example;

FIG. 4 is a diagram illustrating a relationship between an operating time and a drain current;

FIGS. 5A to 5I are cross sectional views illustrating, in sequence, a method of manufacturing the compound semiconductor device according to the first embodiment;

FIG. 6 is a diagram illustrating an etching proceed;

FIG. 7 is a cross sectional view illustrating a structure of a compound semiconductor device according to a second embodiment;

FIG. 8 is a cross sectional view illustrating a structure of a compound semiconductor device according to a third embodiment;

FIGS. 9A to 9B are cross sectional views illustrating, in sequence, a method of manufacturing a compound semiconductor device according to a fourth embodiment;

FIG. 10 is a drawing illustrating a discrete package according to a fifth embodiment;

FIG. 11 is a wiring diagram illustrating a power factor correction (PFC) circuit according to a sixth embodiment;

FIG. 12 is a wiring diagram illustrating a power supply apparatus according to a seventh embodiment;

FIG. 13 is a wiring diagram illustrating a high-frequency amplifier according to an eighth embodiment.

### DESCRIPTION OF EMBODIMENTS

The present inventor extensively investigated into the reasons why it is difficult to obtain good conduction characteristics such as on-resistance and operation speed, when the p-type GaN layer is provided, in prior arts. Then, it was found out that holes in the p-type semiconductor layer diffuse to the channel side of the 2DEG, that the holes move against the electrons, and that the holes are accumulated at a deep portion (bottom portion) of the channel layer right below the source electrode. The accumulated holes raise a potential of the channel and increase on-resistance against electron moving in the channel. Moreover, since the hole accumulation varies a current path, operating speed is affected by the variation. Then the present inventors got the idea to provide a barrier layer which suppresses hole diffusion based on these perceptions.

Embodiments will be detailed below, referring to the attached drawings.

### First Embodiment

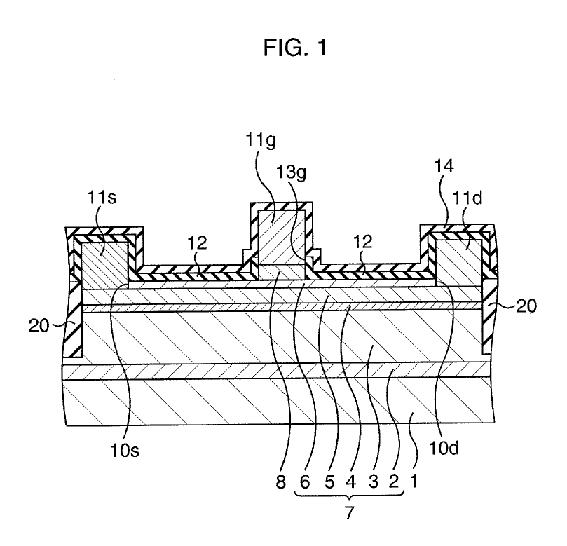

A first embodiment will be described. FIG. 1 is a cross sectional view illustrating a structure of a GaN-based HEMT (compound semiconductor device) according to the first embodiment.

In the first embodiment, as illustrated in FIG. 1, a compound semiconductor stacked structure 7 is formed over a substrate 1 such as Si substrate. The compound semiconductor stacked structure 7 includes a buffer layer 2, an electron channel layer 3, a spacer layer 4, an electron supply layer 5 and a hole barrier layer 6. The buffer layer 2 may be an AlN layer and/or an AlGaN layer of approximately 10 nm to 2000 nm thick, for example. The electron channel layer 3 may be an i-GaN layer of approximately 1000 nm to 3000 nm thick, which is not intentionally doped with an impurity, for example. The spacer layer 4 may be an i-Al_{0.2}Ga_{0.8}N layer of approximately 5 nm thick, which is not intentionally doped with an impurity, for example. The electron supply layer 5 may be an n-type AlGaN (n-Al_{0.2}Ga_{0.8}N) layer of approximately 30 nm thick, for example. The electron supply layer 5 may be doped with approximately 5×10¹⁸/cm³ of Si as an n-type impurity, for example. The hole barrier layer 6 may be an AlN layer of approximately 2 nm thick, for example.

An element isolation region 20 which defines an element region is formed in the compound semiconductor stacked structure 7. In the element region, recesses 10s and 10d are formed in the hole barrier layer 6. A source electrode 11s is formed in the recess 10s, and a drain electrode lid is formed in the recess 10d. The recesses 10s and 10d may be omitted, and the hole barrier layer 6 may remain between the electron supply layer 5, and the source electrode 11s and the drain electrode 11d. A contact resistance is lower and the property is better when the source electrode 11s and the drain electrode 11d are in direct contact with the electron supply layer 5. A cap layer 8 is formed on a region of the hole barrier layer 6 between the source electrode 11s and the drain electrode lid in planar view. The cap layer 8 may be a p-type GaN (p-GaN) layer of approximately 50 nm thick, for example. The cap layer 8 may be doped with approximately 5×10¹⁹/cm³ of Mg as a p-type impurity, for example. The cap layer 8 is an example of the p-type semiconductor layer.

An insulating film 12 is formed so as to cover the source electrode 11s and the drain electrode lid over the hole barrier layer 6. An opening 13g is formed in the insulating film 12 so as to expose the cap layer 8, and a gate electrode 11g is formed in the opening 13g. An insulating film 14 is formed so as to cover the gate electrode 11g over the insulating film 12. While materials used for the insulating films 12 and 14 are not specifically limited, a Si nitride film may be used, for example. The insulating films 12 and 14 are an example of the termination film.

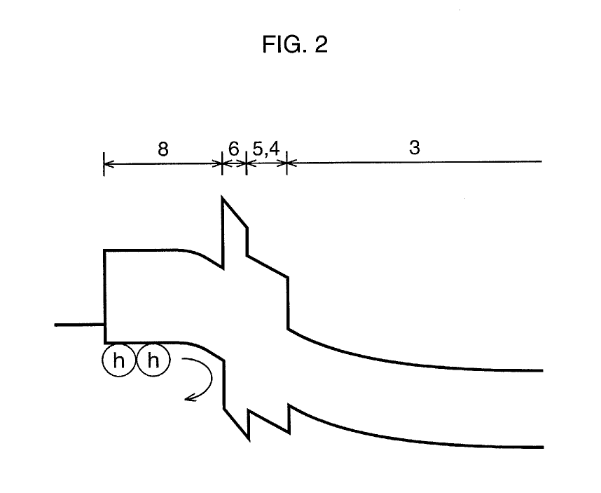

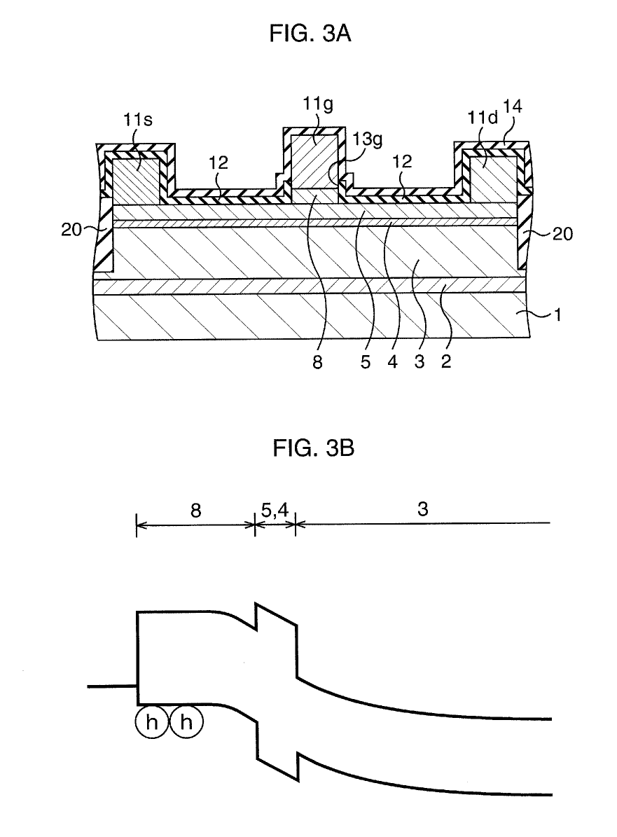

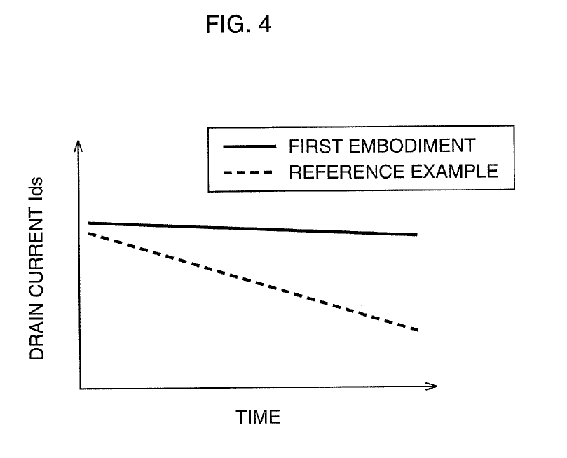

FIG. 2 is a diagram illustrating a band structure beneath the gate electrode 11g of the GaN-based HEMT thus configured. FIG. 3B is a diagram illustrating a band structure of a referential example illustrated in FIG. 3A. As is obvious from FIG. 2 and FIG. 3A, holes easily diffuse up to the channel when on-voltage is applied to the gate electrode 11g in the referential example, which does not include the hole barrier layer 6. On the other hand, holes hardly diffuse from the p-type cap layer 8 up to the channel of 2DEG, even if on-voltage is applied to the gate electrode 11g in the embodiment, since there is provide with the hole barrier layer 6. Therefore, the increase of on-resistance and the variation of current path due to the hole diffusion can be suppressed, and good conduction characteristics can be obtained. For example, stable drain current Id can be obtained in the embodiment, while drain current Id decreases over elapsed time in the referential example, as illustrated in FIG. 4.

When a lattice constant of a nitride semiconductor of the hole barrier layer 6 is smaller than that or the electron supply layer 5, the density of 2DEG in the vicinity of the electron channel layer 3 is higher and on-resistance is lower.

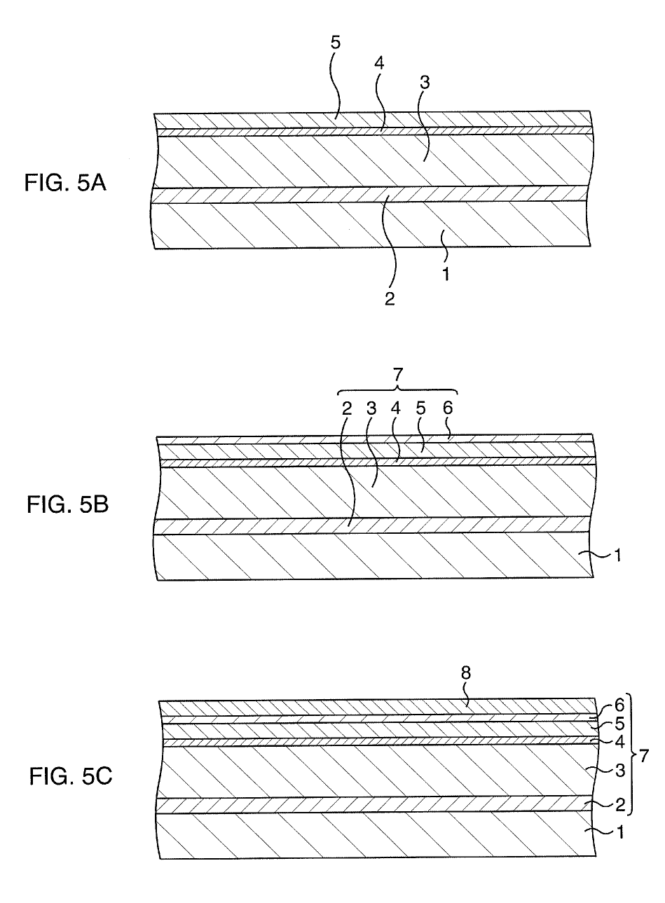

Next, a method of manufacturing the GaN-based HEMT (compound semiconductor device) according to the first embodiment will be explained. FIG. 5A to FIG. 5I are cross sectional views illustrating, in sequence, a method of manufacturing the GaN-based HEMT (compound semiconductor device) according to the first embodiment.

First, as illustrated in FIG. 5A, the buffer layer 2, the electron channel layer 3, the spacer layer 4, and the electron supply layer 5 may be formed over the substrate 1 by a crystal growth process such as metal organic vapor phase epitaxy (MOVPE) and molecular beam epitaxy (MBE). In the process of forming the AlN layer, the AlGaN layer and the GaN layer by MOVPE, a mixed gas of trimethylaluminum (TMA) gas as an Al source, trimethylgallium (TMG) gas as a Ga source, and ammonia (NH₃) gas as a N source, may be used. In the process, on/off of supply and flow rates of trimethylaluminum gas and trimethylgallium gas are appropriately set, depending on compositions of the compound semiconductor layers to be grown. Flow rate of ammonia gas, which is common to all compound semiconductor layers, may be set to approximately 100 ccm to 10 LM. Growth pressure may be adjusted to approximately 50 Torr to 300 Torr, and growth temperature may be adjusted to approximately 1000° C. to 1200° C., for example. In the process of growing the re-type compound semiconductor layers, Si may be doped into the compound semiconductor layers by adding SiH₄ gas, which contains Si, to the mixed gas at a predetermined flow rate, for example. Dose of Si is adjusted to approximately 1×10¹⁸/cm³ to 1×10²⁰/cm³, and to 5×10¹⁸/cm³ or around, for example.

Next, as illustrated in FIG. 5B, the hole barrier layer 6 may be formed over the electron supply layer 5 by a crystal growth process such as MOVPE and MBE, for example. The hole barrier layer 6 may be formed continuously with the buffer layer 2, the electron channel layer 3, the spacer layer 4, and the electron supply layer 5. In this case, to form the hole barrier layer 6, supply of the TMG gas and the SiH₄ gas may be stop, while supply of the TMA gas and the NH₃ gas may be continued. Thus the compound semiconductor stacked structure 7 may be obtained.

Thereafter, as illustrated in FIG. 5C, the cap layer 8 may be formed over the hole barrier layer 6 by a crystal growth process such as MOVPE and MBE, for example. The cap layer 8 may be formed continuously with the buffer layer 2, the electron channel layer 3, the spacer layer 4, the electron supply layer 5, and hole barrier layer 6. Dose of Mg to the cap layer 8 is adjusted to approximately 5×10¹⁹/cm³ to 1×10²⁰/cm³, and to 5×10¹⁹/cm³ or around, for example. Then annealing is performed so as to activate Mg.

Next, as illustrated in FIG. 5D, the element isolation region 20 which defines the element region is formed in the compound semiconductor stacked structure 7 and the cap layer 8. In the process of forming the element isolation region 20, for example, a photoresist pattern is formed over the cap layer 8 so as to selectively expose region where the element isolation region 20 is to be formed, and ion such as Ar ion is implanted through the photoresist pattern used as a mask. Alternatively, the cap layer 8 and the compound semiconductor stacked structure 7 may be etched by dry etching using a chlorine-containing gas, through the photoresist pattern used as an etching mask.

Thereafter, as illustrated in FIG. 5E, the cap layer 8 is etched so as to be remained in a region where the gate electrode is to be formed. In the process of patterning the cap layer 8, for example, a photoresist pattern is formed over the cap layer 8 so as to cover the region where the cap layer 8 is to be remained, and the cap layer 8 is etched by dry etching using a chlorine-containing gas, through the photoresist pattern used as an etching mask.

Then, as illustrated in FIG. 5F, the recesses 10s and 10d are formed in the hole barrier layer 6 in the element region. In the process of forming the recesses 10s and 10d, for example, a photoresist pattern is formed over the compound semiconductor stacked structure 7 and the cap layer 8 so as to expose regions where the recesses 10s and 10d are to be formed, and the hole barrier layer 8 is etched by dry etching using a chlorine-containing gas, through the photoresist pattern used as an etching mask. Next, the source electrode 11s is formed in the recess 10s, and the drain electrode lid is formed in the recess 10d. The source electrode 11s and the drain electrode lid may be formed by a lift-off process, for example. More specifically, a photoresist pattern is formed so as to expose regions where the source electrode 11s and the drain electrode lid are to be formed, a metal film is formed over the entire surface by an evaporation process while using the photoresist pattern as a growth mask, for example, and the photoresist pattern is then removed together with the portion of the metal film deposited thereon. In the process of forming the metal film, for example, a Ta film of approximately 20 nm thick may be formed, and an Al film of approximately 200 nm thick may be then formed. The metal film is then annealed, for example, in a nitrogen atmosphere at 400° C. to 1000° C. (at 550° C., for example) to thereby ensure the ohmic characteristic.

Then as illustrated in FIG. 5G, the insulating film 12 is formed over the entire surface. The insulating film 12 is preferably formed by atomic layer deposition (ALD), plasma-assisted chemical vapor deposition (CVD), or sputtering.

Next, as illustrated in FIG. 5H, the opening 13g is formed in the insulating film 12 so as to expose the cap layer 8 at a position between the source electrode ils and the drain electrode 11d in planar view.

Next, as illustrated in FIG. 5I, the gate electrode 11g is formed in the opening 13g. The gate electrode 11g may be formed by a lift-off process, for example. More specifically, a photoresist pattern is formed so as to expose a region where the gate electrode 11g is to be formed, a metal film is formed over the entire surface by an evaporation process while using the photoresist pattern as a growth mask, for example, and the photoresist pattern is then removed together with the portion of the metal film deposited thereon. In the process of forming the metal film, for example, a Ni film of approximately 30 nm thick may be formed, and a Au film of approximately 400 nm thick may be then formed. Thereafter, the insulating film 14 is formed over the insulating film 12 so as to cover the gate electrode 11g.

The GaN-based HEMT according to the first embodiment may be thus manufactured.

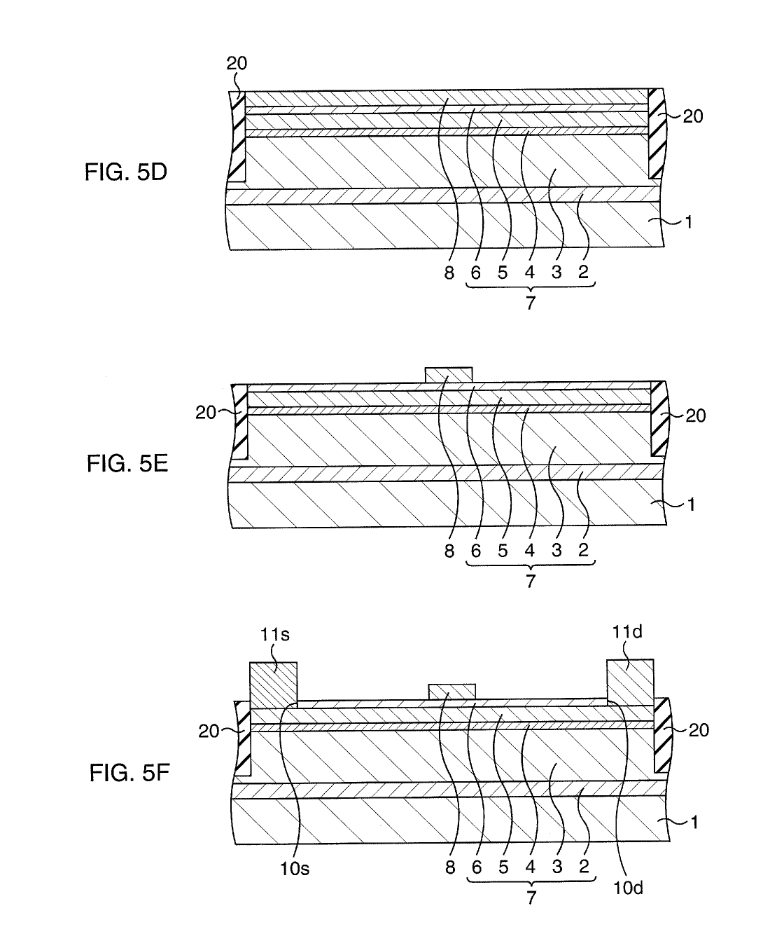

Note that etching selectivity relating to dry etching between GaN of the cap layer 8 and AlGaN of the hole barrier layer 6 is large. Thus, as for etching the cap layer 8, it becomes abruptly difficult for the etching to progress once a surface of the hole barrier layer 6 appears, as illustrated in FIG. 6. In other words, the dry etching with the hole barrier layer 8 used as an etching stopper is capable. Accordingly, the dry etching may be easily controlled. On the other hand, etching selectivity relating to dry etching between GaN of the cap layer 8 and GaN of the electron supply layer 5 is small. Thus, when the GaN-based HEMT of the referential example is manufactured, it is easy for the etching to progress even if a surface of the hole barrier layer 6 appears, as illustrated in FIG. 6. Accordingly, a relative complicated controlling such as a time controlling is conducted.

If there is no hole barrier layer 6, there is a possibility that Mg as a p-type impurity diffuses to the channel during the annealing to activate Mg. The embodiment can the Mg diffusion like that.

Note that the hole barrier layer 6 is not specifically limited to an AlN layer, and an AlGaN layer whose Al fraction is higher than that of the electron supply layer 5 may be used for the hole barrier layer 6, for example. Alternatively, an InAlN layer may be used for the hole barrier layer 6, for example. When an AlGaN layer is used for the hole barrier layer 6, composition of the hole barrier layer 6 may be represented by Al_{y}Ga_{1-y}N (x<y≦1), with composition of the electron supply layer being represented by AlₓGa₁₋ₓN (0<x<1). When an InAlN layer is used for the hole barrier layer 6, composition of the hole barrier layer 6 may be represented by In_{z}Ai_{1-z}N (0≦z≦1), with composition of the electron supply layer being represented by AlₓGa₁₋ₓN (0<x<1). A thickness of the hole barrier layer 6 is preferably 1 nm or more and 3 nm or less (2 nm, for example) if the hole barrier layer 6 is an AlN layer, and preferably 3 nm or more and 8 nm or less (5 nm, for example) if the hole barrier layer 6 is an AlGaN layer or InAlN layer. When the hole barrier layer 6 is thinner than the lower limit of the above-described preferable range, the hole barrier property may be low. When the hole barrier layer 6 is thicker than the upper limit of the above-described preferable range, the normally-off operation may be relatively difficult. Moreover, as described above, when a lattice constant of a nitride semiconductor of the hole barrier layer 6 is smaller than that or the electron supply layer 5, the density of 2DEG in the vicinity of the electron channel layer may be higher and on-resistance may be lower.

### Second Embodiment

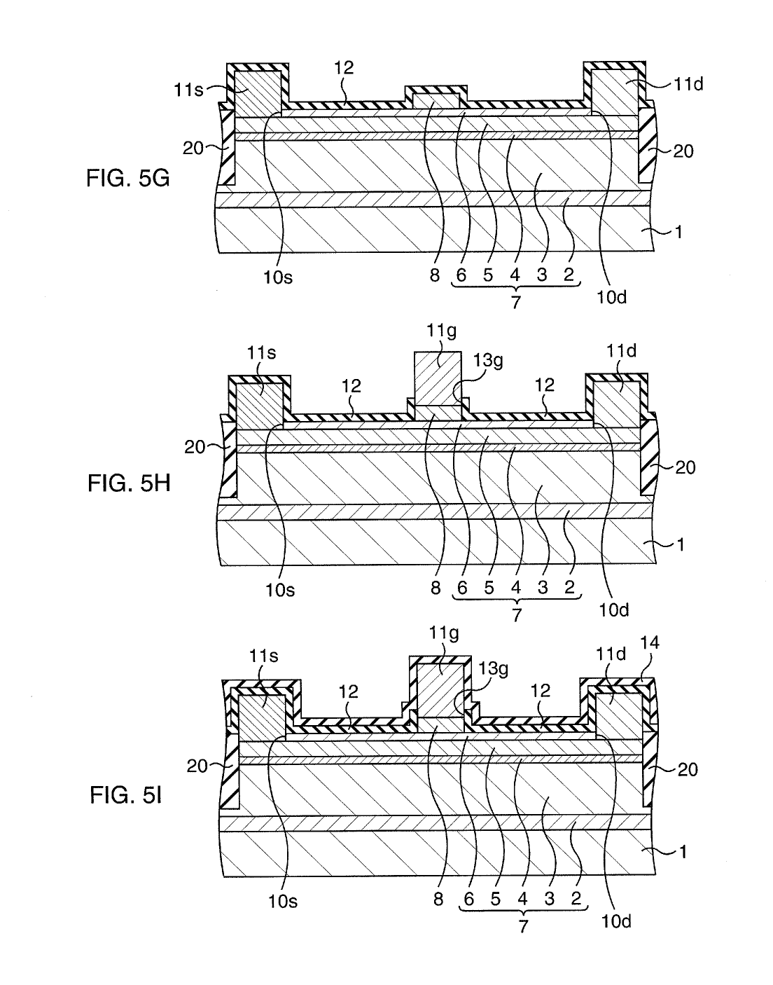

Next, a second embodiment will be explained. FIG. 7 is a cross sectional view illustrating a structure of a GaN-based HEMT (compound semiconductor device) according to the second embodiment.

In contrast to the first embodiment, having the hole barrier layer 6 stretching between the source electrode 11s and the drain electrode 11d in planar view, the hole barrier layer 6 is provided only below the gate electrode 11g in planar view in the second embodiment. Other structure is similar to the first embodiment.

Also the second embodiment thus configured successfully achieves, similarly to the first embodiment, the effects of suppressing the increase of on-resistance and the variation of current path, with the presence of the hole barrier layer 6.

### Third Embodiment

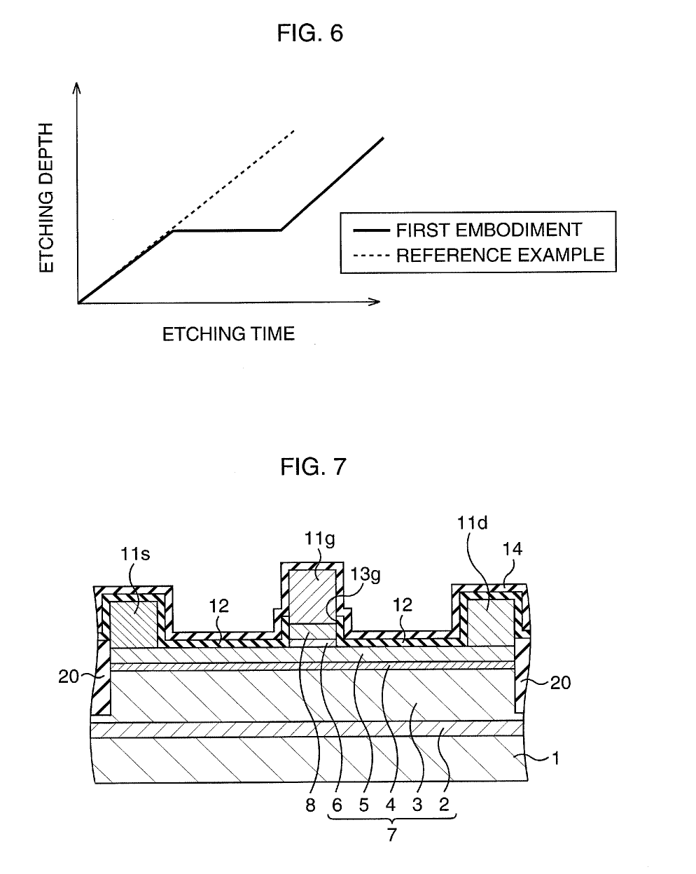

Next, a third embodiment will be explained. FIG. 8 is a cross sectional view illustrating a structure of a GaN-based HEMT (compound semiconductor device) of the third embodiment.

In contrast to the first embodiment, having the gate electrode 11g brought into Schottky contact with the compound semiconductor stacked structure 7, the third embodiment adopts the insulating film 12 between the gate electrode 11g and the compound semiconductor stacked structure 7, so as to allow the insulating film 12 to function as a gate insulating film. In short, the opening 13g is not formed in the insulating film 12, and a MIS-type structure is adopted.

Also the third embodiment thus configured successfully achieves, similarly to the first embodiment, the effects of suppressing the increase of on-resistance and the variation of current path, with the presence of the hole barrier layer 6.

A material for the insulating film 12 is not specifically limited, wherein the preferable examples include oxide, nitride or oxynitride of Si, Al, Hf, Zr, Ti, Ta and W. Aluminum oxide is particularly preferable. Thickness of the insulating film 12 may be 2 nm to 200 nm, and 10 nm or around, for example.

### Fourth Embodiment

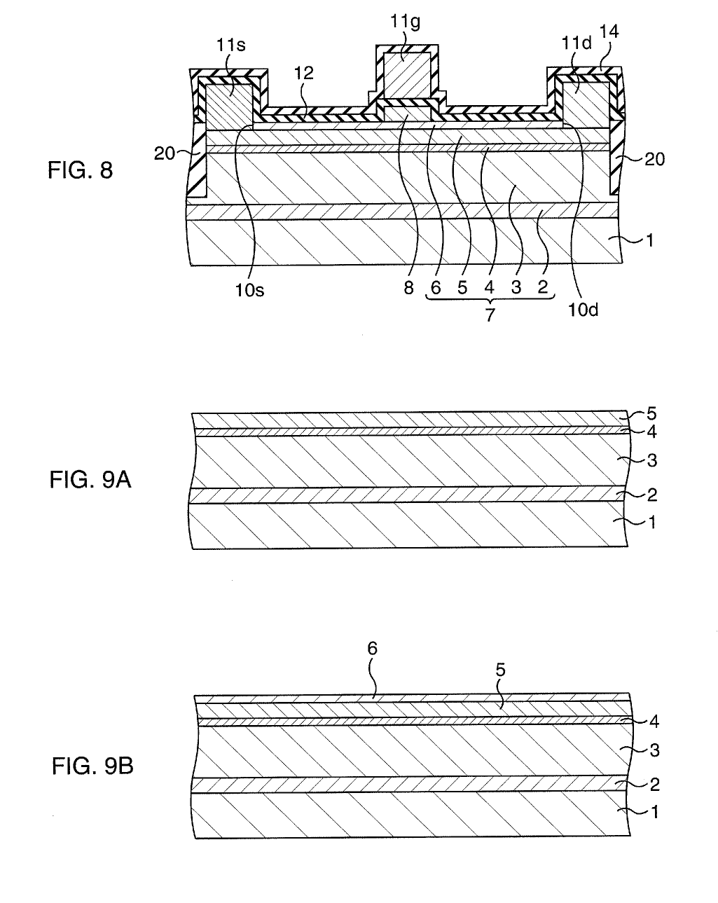

Next, a fourth embodiment will be explained. FIG. 9A to FIG. 9B are cross sectional views illustrating, in sequence, a method of manufacturing a GaN-based HEMT (compound semiconductor device) according to the fourth embodiment.

In the embodiment, first, as illustrated in FIG. 9A, the processes up to the formation of the electron supply layer 5 are conducted similarly to the first embodiment. Note that the electron supply layer 5 is formed so as to be a little bit thicker than in the first embodiment by approximately 2 nm. Then supply of the TMA gas and the TMG gas is stopped, while supply the NH₃ gas is continued, and the temperature is kept at the same or higher. The keeping temperature is preferably between the temperature for forming the electron supply layer 5 and a temperature higher by 50° C. The keeping time depends on the keeping temperature, and it is preferably 5 minutes or around when the temperature is kept at the temperature for forming the electron supply layer 5. The keeping at the certain temperature preferentially eliminates Ga from AlGaN of the electron supply layer 5. Accordingly, the Ga fraction at a surface of the electron supply layer 5 decreases and the Al fraction increases. In short, as illustrated in FIG. 9B, the hole barrier layer 6 is formed in the surface of the electron supply layer 5. Note that the higher keeping temperature is, the more difficult the time controlling is, though the higher the elimination speed is. After the keeping, the processes covering from the formation of the cap layer 8 up to the formation of the insulating film 14 are conducted similarly to the first embodiment.

The fourth embodiment makes control easier than the first embodiment, since kinds of compound semiconductor layers to be formed is fewer than the first embodiment.

After the hole barrier layer 6 is formed through the keeping (annealing), an AlN layer or so on may be formed over the hole barrier layer 6.

### Fifth Embodiment

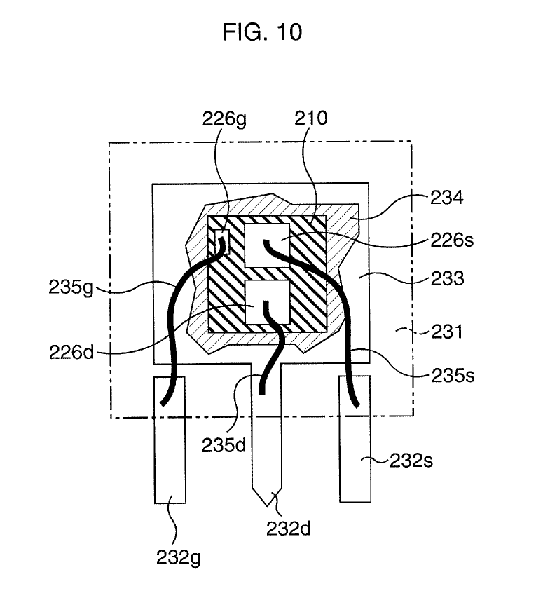

A fifth embodiment relates to a discrete package of a compound semiconductor device which includes a GaN-based HEMT. FIG. 10 is a drawing illustrating the discrete package according to the fifth embodiment.

In the fifth embodiment, as illustrated in FIG. 10, a back surface of a HEMT chip 210 of the compound semiconductor device according to any one of the first to fourth embodiments is fixed on a land (die pad) 233, using a die attaching agent 234 such as solder. One end of a wire 235d such as an Al wire is bonded to a drain pad 226d, to which the drain electrode 11d is connected, and the other end of the wire 235d is bonded to a drain lead 232d integral with the land 233. One end of a wire 235s such as ab Al wire is bonded to a source pad 226s, to which the source electrode 11s is connected, and the other end of the wire 235s is bonded to a source lead 232s separated from the land 233. One end of a wire 235g such as an Al wire is bonded to a gate pad 226g, to which the gate electrode 11g is connected, and the other end of the wire 235g is bonded to a gate lead 232g separated from the land 233. The land 233, the HEMT chip 210 and so forth are packaged with a molding resin 231, so as to project outwards a portion of the gate lead 232g, a portion of the drain lead 232d, and a portion of the source lead 232s.

The discrete package may be manufactured by the procedures below, for example. First, the HEMT chip 210 is bonded to the land 233 of a lead frame, using a die attaching agent 234 such as solder. Next, with the wires 235g, 235d and 235s, the gate pad 226g is connected to the gate lead 232g of the lead frame, the drain pad 226d is connected to the drain lead 232d of the lead frame, and the source pad 226s is connected to the source lead 232s of the lead frame, respectively, by wire bonding. The molding with the molding resin 231 is conducted by a transfer molding process. The lead frame is then cut away.

### Sixth Embodiment

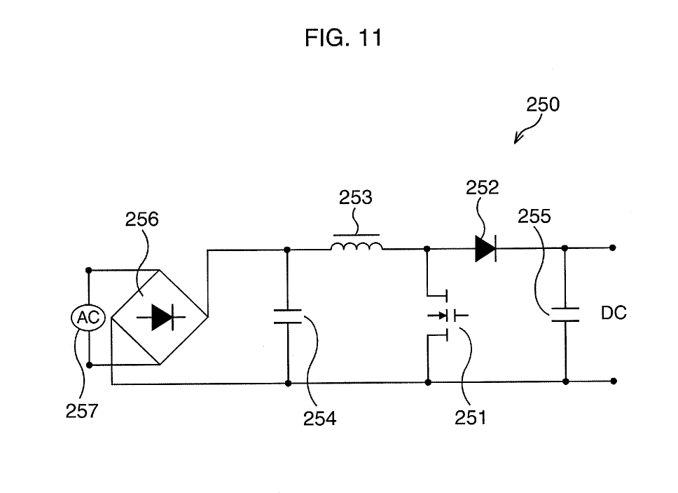

Next, a sixth embodiment will be explained. The sixth embodiment relates to a PFC (power factor correction) circuit equipped with a compound semiconductor device which includes a GaN-based HEMT. FIG. 11 is a wiring diagram illustrating the PFC circuit according to the sixth embodiment.

The PFC circuit 250 has a switching element (transistor) 251, a diode 252, a choke coil 253, capacitors 254 and 255, a diode bridge 256, and an AC power source (AC) 257. The drain electrode of the switching element 251, the anode terminal of the diode 252, and one terminal of the choke coil 253 are connected with each other. The source electrode of the switching element 251, one terminal of the capacitor 254, and one terminal of the capacitor 255 are connected with each other. The other terminal of the capacitor 254 and the other terminal of the choke coil 253 are connected with each other. The other terminal of the capacitor 255 and the cathode terminal of the diode 252 are connected with each other. A gate driver is connected to the gate electrode of the switching element 251. The AC 257 is connected between both terminals of the capacitor 254 via the diode bridge 256. A DC power source (DC) is connected between both terminals of the capacitor 255. In the embodiment, the compound semiconductor device according to any one of the first to fourth embodiments is used as the switching element 251.

In the process of manufacturing the PFC circuit 250, for example, the switching element 251 is connected to the diode 252, the choke coil 253 and so forth with solder, for example.

### Seventh Embodiment

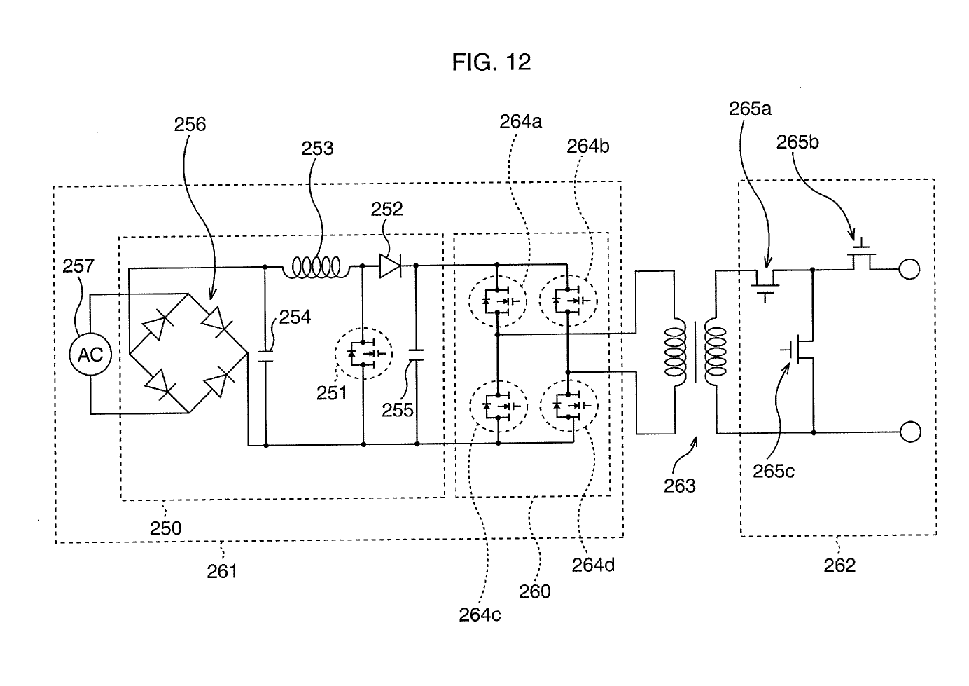

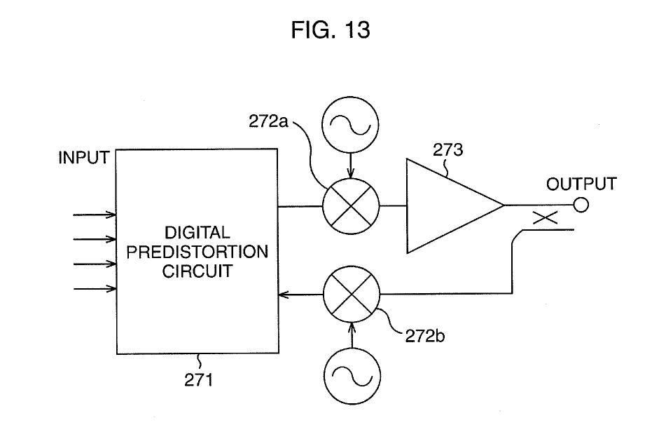

Next, a seventh embodiment will be explained. The seventh embodiment relates to a power supply apparatus equipped with a compound semiconductor device which includes a GaN-based HEMT. FIG. 12 is a wiring diagram illustrating the power supply apparatus according to the seventh embodiment.

The power supply apparatus includes a high-voltage, primary-side circuit 261, a low-voltage, secondary-side circuit 262, and a transformer 263 arranged between the primary-side circuit 261 and the secondary-side circuit 262.

The primary-side circuit 261 includes the PFC circuit 250 according to the sixth embodiment, and an inverter circuit, which may be a full-bridge inverter circuit 260, for example, connected between both terminals of the capacitor 255 in the PFC circuit 250. The full-bridge inverter circuit 260 includes a plurality of (four, in the embodiment) switching elements 264a, 264b, 264c and 264d.

The secondary-side circuit 262 includes a plurality of (three, in the embodiment) switching elements 265a, 265b and 265c.

In the embodiment, the compound semiconductor device according to any one of first to fourth embodiments is used for the switching element 251 of the PFC circuit 250, and for the switching elements 264a, 264b, 264c and 264d of the full-bridge inverter circuit 260. The PFC circuit 250 and the full-bridge inverter circuit 260 are components of the primary-side circuit 261. On the other hand, a silicon-based general MIS-FET (field effect transistor) is used for the switching elements 265a, 265b and 265c of the secondary-side circuit 262.

### Eighth Embodiment

Next, an eighth embodiment will be explained. The eighth embodiment relates to a high-frequency amplifier equipped with the compound semiconductor device which includes a GaN-based HEMT. FIG. 9 is a wiring diagram illustrating the high-frequency amplifier according to the eighth embodiment.

The high-frequency amplifier includes a digital predistortion circuit 271, mixers 272a and 272b, and a power amplifier 273.

The digital predistortion circuit 271 compensates non-linear distortion in input signals. The mixer 272a mixes the input signal having the non-linear distortion already compensated, with an AC signal. The power amplifier 273 includes the compound semiconductor device according to any one of the first to fourth embodiments, and amplifies the input signal mixed with the AC signal. In the illustrated example of the embodiment, the signal on the output side may be mixed, upon switching, with an AC signal by the mixer 272b, and may be sent back to the digital predistortion circuit 271.

Composition of the compound semiconductor layers used for the compound semiconductor stacked structure is not specifically limited, and GaN, AlN, InN and so forth may be used. Also mixed crystals of them may be used.

Configurations of the gate electrode, the source electrode and the drain electrode are not limited to those in the above-described embodiments. For example, they may be configured by a single layer. The method of forming these electrodes is not limited to the lift-off process. The annealing after the formation of the source electrode and the drain electrode is omissible, so long the ohmic characteristic is obtainable. The gate electrode may be annealed.

In the embodiments, the substrate may be a silicon carbide (SiC) substrate, a sapphire substrate, a silicon substrate, a GaN substrate, a GaAs substrate or the like. The substrate may be any of electro-conductive, semi-insulating, and insulating ones.

According to the compound semiconductor devices and so forth described above, the good conduction characteristics can be obtained while achieving normally-off operation, with the presence of the hole barrier layer.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device comprising:
a substrate;
an electron channel layer and an electron supply layer formed over the substrate;
a gate electrode, a source electrode and a drain electrode formed on or above the electron supply layer;
a p-type semiconductor layer formed between the electron supply layer and the gate electrode; and
a hole barrier layer formed between the electron supply layer and the p-type semiconductor layer, a band gap of the hole barrier layer being larger than that of the electron supply layer.

2. The compound semiconductor device according to claim 1, wherein
composition of the electron supply layer is represented by AlₓGa₁₋ₓN (0<x<1), and
composition of the hole barrier layer is represented by Al_{y}Ga_{1-y}N (x<y≦1).

3. The compound semiconductor device according to claim 1, wherein
composition of the electron supply layer is represented by AlₓGa₁₋ₓN (0<x<1), and
composition of the hole barrier layer is represented by In_{z}Ai_{1-z}N (0≦z≦1).

4. The compound semiconductor device according to claim 1, wherein the electron channel layer is a GaN layer.

5. The compound semiconductor device according to claim 1, wherein the p-type semiconductor layer is a GaN layer which contains Mg.

6. The compound semiconductor device according to claim 1, further comprising a gate insulating film formed between the gate electrode and the p-type semiconductor layer.

7. The compound semiconductor device according to claim 1, further comprising a termination film which covers the electron supply layer in each of a region between the gate electrode and the source electrode and a region between the gate electrode and the drain electrode.

8. A power supply apparatus comprising
a compound semiconductor device, which comprises:
a substrate;
an electron channel layer and an electron supply layer formed over the substrate;
a gate electrode, a source electrode and a drain electrode formed on or above the electron supply layer;
a p-type semiconductor layer formed between the electron supply layer and the gate electrode; and
a hole barrier layer formed between the electron supply layer and the p-type semiconductor layer, a band gap of the hole barrier layer being larger than that of the electron supply layer.

9. An amplifier comprising
a compound semiconductor device, which comprises:
a substrate;
an electron channel layer and an electron supply layer formed over the substrate;
a gate electrode, a source electrode and a drain electrode formed on or above the electron supply layer;
a p-type semiconductor layer formed between the electron supply layer and the gate electrode; and
a hole barrier layer formed between the electron supply layer and the p-type semiconductor layer, a band gap of the hole barrier layer being larger than that of the electron supply layer.

10. A method of manufacturing a compound semiconductor device, comprising:
forming an electron channel layer and an electron supply layer over the substrate;
forming a gate electrode, a source electrode and a drain electrode on or above the electron supply layer;
forming a p-type semiconductor layer which is located between the electron supply layer and the gate electrode, before the forming the gate electrode; and
forming a hole barrier layer which is located between the electron supply layer and the p-type semiconductor layer, before the forming the p-type semiconductor layer, a band gap of the hole barrier layer being larger than that of the electron supply layer.

11. The method of manufacturing a compound semiconductor device according to claim 10, wherein
composition of the electron supply layer is represented by AlₓGa₁₋ₓN (0<x<1), and
composition of the hole barrier supply layer is represented by Al_{y}Ga_{1-y}N (x<y≦1).

12. The method of manufacturing a compound semiconductor device according to claim 10, wherein
composition of the electron supply layer is represented by AlₓGa₁₋ₓN (0<x<1), and
composition of the hole barrier supply layer is represented by In_{z}Ai_{1-z}N (0≦z≦1).

13. The method of manufacturing a compound semiconductor, device according to claim 10, wherein the forming the hole barrier supply layer comprises eliminating Ga from a surface of the electron supply layer.

14. The method of manufacturing a compound semiconductor device according to claim 10, wherein the forming the p-type semiconductor layer comprises performing patterning by dry etching with the hole barrier layer as an etching stopper.

15. The method of manufacturing a compound semiconductor device according to claim 10, wherein the electron channel layer is a GaN layer.

16. The method of manufacturing a compound semiconductor device according to claim 10, wherein the p-type semiconductor layer is a GaN layer which contains Mg.

17. The method of manufacturing a compound semiconductor device according to claim 10, further comprising forming a gate insulating film between the gate electrode and the p-type semiconductor layer.

18. The method of manufacturing a compound semiconductor device according to claim 10, further comprising forming a termination film which covers the electron supply layer in each of a region between the gate electrode and the source electrode and a region between the gate electrode and the drain electrode.
